(19) United States
(12) Patent Application Publication
(10) Pub. No.: US 2018/0059032 A1
(43) Pub. Date: Mar. 1, 2018

(54) DEVICE AND METHOD FOR DETECTING DEFECTS IN BONDING ZONES BETWEEN SAMPLES SUCH AS WAFERS

(71) Applicant: FOGALE NANOTECH, Nîmes (FR)

(72) Inventor: Sylvain PERROT, Palaiseau (FR)

(73) Assignee: FOGALE NANOTECH, Nîmes (FR)

(21) Appl. No.: 15/556,988

(22) PCT Filed: Mar. 10, 2016
(86) PCT No.: PCT/EP2016/055071

§ 371 Date: Sep. 8, 2017

(30) Foreign Application Priority Data
Mar. 13, 2015 (FR) 1552076

(51) Int. Cl. G01N 21/95; G01B 9/02; G01N 21/84; H01L 21/683; H01L 21/66

(52) U.S. Cl. CPC G01N 21/9501; G01B 9/0209; G01N 21/8422; H01L 2221/68327; H01L 21/6836; H01L 22/12; G01B 9/0201

(57) ABSTRACT

A measurement device is provided for inspecting a bonding zone between samples, including a low-coherence interferometer illuminated by a polychromatic light source having a measurement arm crossing the connection zone and a reference arm, at least one optical detector and optical and/or mechanical conditioning apparatus arranged to enable the acquisition of at least two interference measurements having different phase conditions between a measurement optical beam coming from the measurement arm and a reference optical beam coming from the reference arm; and calculation apparatus provided to calculate contrast information relating to the interference and to search, on the basis of the contrast information, for defects in the bonding zone.

### TECHNICAL FIELD

The present invention relates to a device and a method for detecting defects in bonding zones between samples. It relates in particular to a device and a method for detecting voids or bubbles in bonding zones between samples in the form of wafers.

The field of the invention is more particularly but non limitatively that of inspecting bonding zones in micro-electronics, MEMs or integrated optics.

### STATE OF THE PRIOR ART

When certain methods for three-dimensional integration of integrated circuits are implemented, in particular by stacking, it is necessary to thin wafers by carrying out grinding or polishing operations. In order to carry out these operations, the wafer to be thinned is temporarily fixed by bonding onto a rigid support such as a thicker wafer. This makes it possible to ensure the rigidity of the wafer to be thinned, in order to be able to reduce its thickness uniformly. Usually, the wafer is bonded along its face that already comprises structures, in order to be thinned via its back face.

Sometimes, gas bubbles or voids form in the bonding zone constituted by the layer of adhesive making it possible for the assembly to be formed. As the gas is compressible, the wafer to be thinned deforms opposite the bubbles during the passage of the grinder and its final thickness is greater at these locations. The loss of homogeneity of thickness obtained compromises the rest of the manufacturing process. This effect is especially inconvenient with bubbles the diameter of which is greater than a few tens of microns.

It is therefore necessary to be able to identify the presence of bubbles after the assembly or the bonding of the wafer onto the support and before the grinding operation. Moreover, this inspection must be carried out quickly, for example in less than 10 minutes for the entire surface.

Acoustic microscopy and X-ray tomography are effective for detecting this type of defect. However, their implementation is difficult: the acquisition times are long, and the wafer must be dipped in a bath for acoustic microscopy.

Insofar as the support is very often polished, made from silicon or glass, and therefore transparent at optical wavelengths in the near infrared, the use of an optical measurement through this support can be envisaged.

For example the document US 2012/0320380 is known, which describes a device of the OCT type with a double configuration making it possible to measure the distance to the interfaces of a bonding zone, or the thickness of this zone directly, in order to detect the defects. This system however only allows measurements to be carried out singly, and is therefore slow.

Document US 2014/0333936 is also known, which describes a full-field optical interferometer making it possible to measure the thickness of a bonding zone according to a field of view.

The known optical detection systems however have the drawback of also detecting or “‘seeing” all the structures present on the surface of the wafer to be thinned. It is difficult under these conditions to distinguish the bubbles or the voids of these structures, which reduces both the reliability and the performance of the algorithms utilized for the automatic detection of bubbles.

More generally, this problem of the detection of bubbles or voids can arise for all types of bonding. Thus, the bubbles searched for can be situated within a thickness of adhesive, of oxide, or can even be a pocket of gas between two slices or two wafers directly merged.

Similarly, this problem of the detection of bubbles or voids can arise for all types of bonding between samples that are not wafers, in other contexts than microelectronics.

A purpose of the present invention is to propose a device and a method that allows rapid and robust detection of defects such as bubbles or voids in a bonding zone between samples, at least one of which is substantially transparent at optical wavelengths.

A further purpose of the present invention is to propose such a device and such a method that is not disturbed by the presence of reliefs or patterns in the bonding zone.

A further purpose of the present invention is to propose such a device and such a method that allows a rapid detection of defects over an extensive surface area.

A further purpose of the present invention is also to propose such a method that allows a rapid detection of bubbles in bonding zones between a wafer to be thinned and a support.

### DISCLOSURE OF THE INVENTION

This objective is achieved with a measurement device for inspecting a bonding zone between samples, comprising a low coherence interferometer illuminated by a polychromatic light source with a measurement arm passing through said bonding zone and a reference arm.

Said device being characterized in that it also comprises:

at least one optical detector and optical or mechanical conditioning means arranged in order to allow the acquisition of at least two measurements of interferences with different phase conditions between a measurement optical beam originating from the measurement arm and a reference optical beam originating from the reference arm; and

calculation means arranged to calculate an information of the contrast of said interferences, and on the basis of said contrast information to search for defects in said bonding zone.

The polychromatic light source can comprise any type of light source the spectral width of emission of which is sufficiently wide to guarantee a very short coherence length, for example of the order of a few microns to several tens of microns. This light source can comprise, for example, a heat source (halogen, etc), a light-emitting diode (LED), a super-light-emitting diode (SLED), etc.

The interferometer is called “low coherence” insofar as it is illuminated by a light source with low coherence length.

It is arranged so that the light from the source transmitted in the measurement arm passes through the bonding zone, and thus generates a measurement beam the optical path of which depends on the local optical properties of the bonding zone.

It is noted that the optical path (or the optical length) of a beam corresponds to the geometrical distance travelled multiplied by the refractive index of the medium passed through.

According to embodiments, the device according to the invention can comprise a low coherence interferometer operating by transmission.

This interferometer can be for example of the Mach-Zehnder type, with a measurement arm in which the measurement beam passes through the bonding zone.

According to preferential embodiments, the device according to the invention can comprise a low coherence interferometer operating by reflection.

In this case, the light originating from the optical source and injected into the measurement arm passes through the bonding zone, and undergoes a partial reflection on an interface of this bonding zone (for example, the face of the wafer in contact with the adhesive), which makes it possible to generate a measurement beam that passes (back and forth) through the bonding zone.

The interferometer can be then arranged for example according to a Michelson configuration, with a separator element such as a beam splitter or a splitter cube, a reference arm terminated by a mirror, and a measurement arm terminated by the bonding zone.

The interferometer can also be arranged according to a Linnik configuration. This configuration is similar to the Michelson configuration, with in addition, optics or objectives inserted in the measurement and reference arms.

According to embodiments, the device according to the invention can comprise mechanical conditioning means arranged so as to carry out at least one of the following functions:

varying the difference of the optical path between the measurement arm and the reference arm of the interferometer;

moving the interferometer relative to the bonding zone so as to vary the optical path in the measurement arm;

generating a movement along the axis of the reference optical beam of a reflective element so as to vary the optical path in the reference arm;

The mechanical conditioning means can comprise, for example, mechanical means of translation and/or rotation.

According to embodiments, the device according to the invention can comprise two optical detectors inserted into two output arms of the interferometer so as to allow the implementation of two measurements of interferences in phase opposition.

According to embodiments, the device according to the invention can comprise an interferometer arranged so as to allow the generation of a measurement beam and a reference beam with substantially orthogonal polarizations.

It can comprise, for example, an interferometer with a polarizing beam splitter element (for example a polarization splitter cube) and quarter wave retardation plates inserted into the measurement and reference arms.

According to embodiments, the device according to the invention can then comprise:

an optical conditioning means in the form of a phase modulator inserted between the interferometer and an optical detector;

a plurality of optical detectors, and optical conditioning means in the form of retardation plates arranged so as to allow the acquisition of a plurality of measurements of interferences with different phase conditions.

According to embodiments, the device according to the invention can comprise one or more optical detectors with a plurality of measurement pixels, and optical imaging elements arranged so as to image, according to at least one field of view, the bonding zone on said optical detector or detectors.

The optical detector or detectors can comprise in particular an array or in-line detector, for example of the CCD, CMOS or InGaAs type.

The device according to the invention can then comprise a full-field interferometer capable of producing measurements corresponding to different points of the bonding zone simultaneously over a plurality of pixels of the optical detector or detectors.

According to another aspect, a method is proposed for inspecting a bonding zone between samples, utilizing a low coherence interferometer illuminated by a polychromatic light source with a measurement arm passing through said bonding zone and a reference arm,

said method comprising the steps of:

acquiring at least two measurements of interferences with different phase conditions between a measurement optical beam originating from the measurement arm and a reference optical beam originating from the reference arm;

calculating a contrast information of said interferences; and

searching, on the basis of said contrast information, for defects in said bonding zone.

According to a preferred embodiment, the method according to the invention can comprise a step of searching for defects in the form of voids or bubbles.

The contrast of the interferences depends on the difference in optical intensity detected between a constructive interference condition (measurement and reference beams in phase) and a destructive interference condition (measurement and reference beams in opposite phase), or in other words the difference in intensity between the light and dark fringes of the interferogram.

In a low coherence interferometer (or illuminated by a source with a short coherence length), the contrast of the interferences is maximal when the optical paths of the reference and measurement waves are substantially identical. It reduces rapidly when the differences in optical paths between the reference and measurement beams become comparable to or greater than the coherence length of the source, tending towards zero.

Defects such as bubbles cause optical path differences in the bonding zone, due to the difference in refractive index:

the optical length Lₙ of a bonding zone of thickness E filled with adhesive of index n is Lₙ=nE;

the optical length Lᵥ of a bonding zone of thickness E without adhesive (therefore with a void or bubble) is Lᵥ=E;

Thus, the presence of a bubble causes a variation in optical length of the bonding zone equal to dL=Lᵥ−Lₙ=(1−n)E.

If the measurement is carried out by reflection, the variation in optical length “seen” by the measurement beam is doubled: dL=2(1−n)E.

Thus, according to the invention, by using a light source the coherence length of which is sufficiently short, and by suitably adjusting the length of the measurement and reference arms of the interferometer, the presence of a defect that causes an optical path difference dL in the measurement arm can be detected based on a measurement of the contrast of the interferences.

According to a particularly advantageous aspect of the invention, the measurement of the contrast of the interferences is largely independent of the reflectivity and/or small phase variations of the measurement beam. Thus, for example, if the measurement is carried out by reflection with a measurement beam originating from a reflection on an interface of the bonding zone, it is much less disturbed by the presence of patterns at this interface than the methods of the prior art based on measurements of distance or thickness.

The invention thus allows a simple and robust detection of the presence of defects. Moreover, it makes it possible to detect all types of defects that generate a significant variation in refractive index locally.

In another particularly advantageous aspect, the method according to the invention generally requires the acquisition of fewer images or measurements than methods based on a measurement of the thickness of the bonding zone. It can therefore be carried out much more rapidly.

The invention thus makes it possible to detect defects at a high rate. It also allows a complete analysis of a bonding zone (for example over a complete wafer), in a minimum amount of time.

The method according to the invention can comprise a step of adjusting the interferometer so that the optical path difference between the measurement arm and the reference arm is less than the coherence length of the light source when at least one of the following conditions is satisfied:

the measurement optical beam passes through a portion of the bonding zone without a defect;

the measurement optical beam passes through a part of the bonding zone with a defect of a predetermined nature (for example a bubble or a void).

In the first case, the fringe contrast is maximal in the absence of defects, and reduces in the presence of bubbles or other significant defects.

In the second case, the fringe contrast is minimal or zero in the absence of defects, and increases in the presence of bubbles.

This adjustment step can be repeated periodically, during the inspection of a sample, for example in order to compensate for slow variations in the length of the optical path of the measurement beam in the absence of defects, in particular if the thickness or position of the bonding area varies.

According to embodiments, the method according to the invention can comprise a step of comparison of an item of contrast information with a threshold or a range of contrast values.

The result of this comparison can be used to identify a presence or absence of a defect.

This threshold or this range of values can be fixed or predefined.

This threshold or this range of values can also be variable or adaptive. This can make it possible, for example, to adjust the defect detection criteria locally in the presence of slow variations in the length of the optical path of the measurement beam from one measurement to another in the absence of defects. In this case, the defects appear as significant local variations in the contrast and can be detected by applying a threshold or local value range criterion.

According to embodiments, the method according to the invention can comprise steps of:

acquiring a plurality of contrast measurements; and

detecting local variations in the contrast in said plurality of contrast measurements, in order to detect the defects.

According to embodiments, the method according to the invention can comprise a step of sequential acquisition of a plurality of measurements of interferences by varying at the level of an optical detector the phase difference between the measurement beam and the reference beam.

According to embodiments, the method according to the invention can comprise a step of acquisition of a plurality of measurements of interferences over a plurality of optical detectors with different phase shifts between the measurement beams and the reference beams respectively incident on said optical detectors.

These acquisitions can be simultaneous.

According to embodiments, the method according to the invention can be implemented for searching for defects in a bonding or adhesion zone between samples at least one of which is in the form of a wafer.

### DESCRIPTION OF THE FIGURES AND EMBODIMENTS

Other advantages and characteristics of the invention will become apparent on examination of the detailed description of implementations and embodiments which are in no way limitative, and the following attached drawings:

FIG. 1 shows a first embodiment of a device according to the invention,

FIG. 2 shows the measurement principle,

FIG. 3 shows a second embodiment of a device according to the invention,

FIG. 4 shows a third embodiment of a device according to the invention,

FIG. 5 shows a fourth embodiment of a device according to the invention.

It is well understood that the embodiments which will be described hereinafter are in no way limitative. Variants of the invention can be envisaged comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In particular, all the variants and all the embodiments described can be combined with one another if there is no objection to this combination from a technical point of view.

In the figures, the elements common to several figures retain the same reference.

For the sake of clarity, only the elements necessary for understanding the invention are shown in the figures. The other elements, the implementation of which is conventional and does not present any particular problems to a person skilled in the art are generally omitted or shown in a purely diagrammatic form.

In particular, the optical elements necessary for conditioning the optical beams (lenses, compensating blades, etc.) are only partially represented.

Similarly, the mechanical elements necessary for holding the samples (wafer support, optionally suction or vacuum support) are not shown.

It is well understood that the elements common to the various embodiments presented are not systematically described for each one thereof, for reasons of brevity.

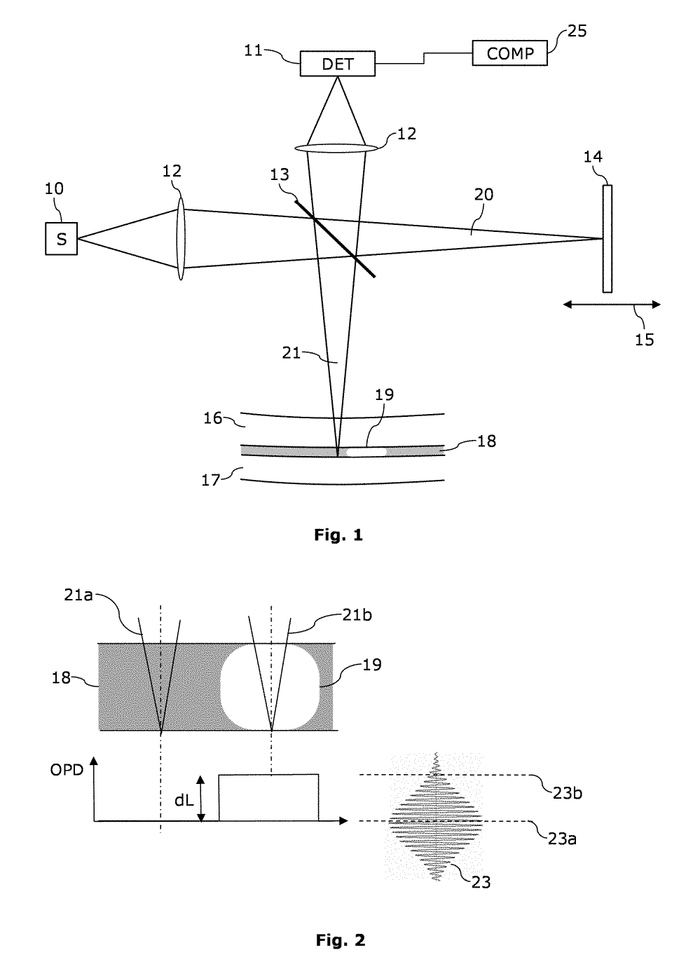

FIGS. 1 to FIG. 5 illustrate various embodiments of a device according to the invention, which implement a low-coherence interferometer operating by reflection.

This interferometer is arranged to carry out measurements in a bonding zone 18 filled with adhesive and located between a wafer 17 to be thinned and a support 16. The measurement is carried out through the support 16.

In practice, the wafer 17 is already processed and its surface facing the bonding zone 18 can be metalized and/or comprise etched or deposited structures.

In the embodiments shown in relation to FIG. 1 to FIG. 5, the interferometer is illuminated by a wide-spectrum source 10. Preferably, this source is a halogen source that has a wide spectrum in the near infrared, capable of passing through layers of silicon.

With reference to FIG. 1, a first embodiment of the invention will now be described in detail.

The light from the source 10 is directed towards a beam splitter 13 that constitutes the core of the interferometer.

This beam splitter 13 separates the light from the source into a reference beam 20 that travels through a reference arm of the interferometer and a measurement beam 21 that travels through a measurement arm of this interferometer.

The reference beam 20 is reflected by a reference mirror 14.

The measurement beam 21 is directed towards the bonding zone 18. It passes through it in order to be reflected on the surface of the wafer 17.

The reference 20 and measurement 21 beams are then directed to a detector 11 that makes it possible to measure the interferences thereof.

According to a preferential embodiment, the detector 11 is a linear detector of the InGaAs type, which makes it possible to obtain a high sensitivity in the infrared and high acquisition rates.

According to another embodiment, the detector 11 is an array detector, preferably of the CMOS type. Such a detector has the advantage of being less expensive, while allowing acceptable acquisition rates.

The device also comprises imaging elements (lenses, objectives, isolators, etc.) that make it possible to illuminate the bonding zone 18 according to a measuring range, and to image this measuring range on the detector 11. These imaging elements are shown diagrammatically in the form of lenses 12.

The reference mirror 14 is mounted on mechanical translation elements 15 that make it possible to move it so as to vary the difference in optical paths between the measurement 21 and reference 20 beams. Preferably, these mechanical translation elements 15 comprise a piezoelectric actuator that makes it possible to carry out precise and rapid movements.

According to a variant of this embodiment, the reference mirror 14 comprises a part that is mobile in rotation about an axis of rotation substantially parallel to the axis of the reference beam 20. This rotating part has a profile that makes it possible to modulate the length of the optical path of the reference beam 20 during its rotation.

FIG. 2 illustrates the measurement principle of the invention.

The measurement beam 21a illustrates a measurement situation in a “normal” zone, without a defect, of the bonding zone 18: it passes through this bonding zone 18 through a homogeneous thickness of adhesive before being reflected on the surface of the wafer 17.

The measurement beam 21b illustrates a measurement situation in an area of the bonding zone 18 with a bonding defect: it passes through this bonding zone 18 through a gas bubble 19 before being reflected on the surface of the wafer 17.

As explained previously, the presence of the bubble 19 generates a difference in the optical path of the measurement beam dL=2(1−n)E, where E is the thickness of the bonding zone and n is the refractive index of the adhesive.

In the embodiment shown, the interferometer is balanced so that the length of the optical path of the reference beam 20 is substantially equal to the length of the measurement beam 21 in the situation in which the latter originates from a reflection on the surface of the wafer 17 through the bonding zone 18 with a normal thickness of adhesive. This situation corresponds to that of the measurement beam 21a in FIG. 2. In this case, the optical path difference OPD between the measurement beam 21a and the reference beam 20 is zero (OPD=0) and the contrast of the interferences between these two beams for small variations around this position is maximal. In fact, as shown in FIG. 2, movement takes place around the position 23a in the interferogram 23 of the source.

When the measurement beam passes through a bubble (beam 21b), an optical path difference OPD appears between the measurement beam 21a and the reference beam 20 equal to dL(OPD=dL). If this optical path difference OPD is at least comparable to the coherence length of the source 10, the contrast of the interferences 23 between these two beams becomes low or zero. This situation is illustrated by the position 23b in the interferogram 23 of the source.

With the adjustment of the interferometer previously described, a contrast image is thus obtained in which the bubbles appear with low contrast levels and the normal areas appear with high contrast levels.

Alternatively, the interferometer can be balanced so that condition OPD=0 is produced when measurement beam 21 passes through a bubble (situation of the beam 21b). A contrast image is thus obtained in which the bubbles appear with high contrast levels and the normal areas appear with low contrast levels.

By way of a non-limitative example, by implementing a CMOS type optical detector 11 and a filtered halogen light source 10 in order to allow wavelengths greater than 1075 nm to pass, a coherence length of the order of 8 μm is obtained. It is thus possible to detect a bubble in a thickness of adhesive of the order of 10 μm.

A measurement method will now be described that implements the device described in FIG. 1.

This measurement method, as well as those implemented in relation to the other embodiments described, is implemented in calculation means 25 of the computer or microcontroller type etc., which are arranged so as to control the acquisition of the measurements and to carry out the other operations necessary for the operation of the device.

Firstly, the interferometer is balanced in order to produce the condition of equality of optical paths in a predefined measurement condition (for example the “normal” measurement situation 21a).

In order to carry out a measurement, the reference mirror 14 is moved in successive steps to acquire, with the optical detector 10, interference images in the field of view with different optical path difference OPD (or phase shift) conditions.

These interference images must be acquired in such a way as to allow sampling of the interferogram 23 under conditions that make it possible to deduce an item of contrast (or of amplitude) information therefrom.

For this purpose, a phase-shift reconstruction technique (phase stepping) is preferably implemented, by generating suitable reference mirror displacements 14. It is possible for example to acquire 3 images that are out of phase by 120 degrees.

A contrast image is then calculated, each point of which is representative of the variation in intensity at this point between the different interference images.

On the basis of the contrast image, the defects that appear as significantly different areas (brighter or darker depending on the interferometer setting) of the “normal” areas can be detected. For this purpose, thresholding can be applied for example.

In the case where the wafer 17 is not totally flat, the intensity of the contrast image can vary continuously. In this case, adaptive thresholding or a detection of local variations can be applied in order to locate defects.

The embodiment in FIG. 1 has the drawback of requiring the acquisition of several successive images, which can be time-consuming.

However, it should be noted that it is sufficient to acquire a few images (at least two) over a period of the interferogram 23 in order to obtain the necessary information, which is limited to contrast.

The method according to the invention, even in this embodiment, therefore remains much more rapid and robust than the methods of the prior art that require measurement of the variations in thickness of the bonding zone 18. In fact, in this case, it would be necessary to sample the entire interferogram 23 between the planes 23a and 23b, and thus to acquire many more images

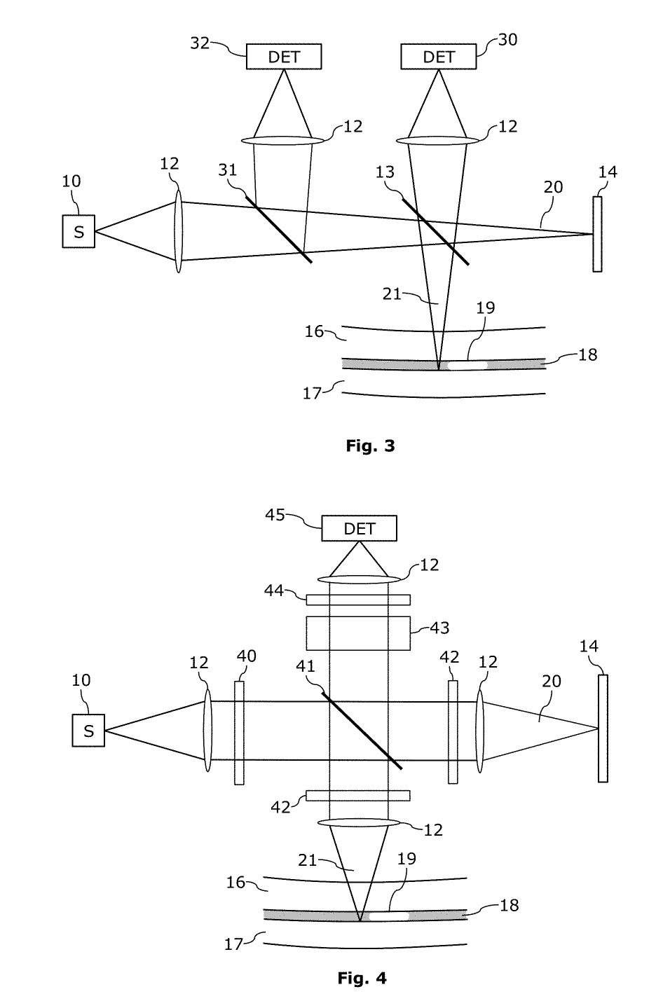

With reference to FIG. 3, a second embodiment of a device according to the invention will now be described.

As in the embodiment in FIG. 1, the interferometer is illuminated by a wide-spectrum source 10 of the halogen type.

The light from the source 10 is directed towards a beam splitter 13 that constitutes the core of the interferometer.

The beam splitter 13 separates the light of the source into a reference beam 20 that travels through a reference arm of the interferometer and a measurement beam 21 that travels through a measurement arm of this interferometer.

The reference beam 20 is reflected by a reference mirror 14.

The measurement beam 21 is directed towards the bonding zone 18. It passes through it in order to be reflected on the surface of the wafer 17.

The reference 20 and measurement 21 beams are then recombined by the beam splitter 13 of the interferometer in order to generate two pairs of reference 20 and measurement 21 beams emerging respectively along the two faces of this beam splitter 13.

As in the embodiment in FIG. 1, a first pair of reference 20 and measurement 21 beams is directed to a first optical detector 30.

The second pair of reference 20 and measurement 21 beams is directed (at least partially) to a second optical detector 32 by means of a detection beam splitter 31 inserted between the beam splitter 13 of the interferometer and the optical source 10.

As previously, the device also comprises imaging elements (lenses, objectives, isolators, etc.) that make it possible to illuminate the bonding zone 18 according to a measuring range, and to image this measuring range on the first optical detector 30 and the second optical detector 32. These imaging elements are shown diagrammatically in the form of lenses 12.

This embodiment allows the simultaneous acquisition of two interference images in opposite phase on the first optical detector 30 and the second optical detector 32, respectively. This result is obtained by virtue of the fact that the beam splitter of the interferometer 13 introduces (like most couplers) a phase shift of −90 degrees into the reflected beams with respect to the transmitted beams.

Thus, in this embodiment, it is no longer necessary to move an element of the interferometer in order to obtain a measurement of the contrast of the interferences. At each moment, images are obtained on the two optical detectors 30, 32, the difference in intensity of which is representative of this contrast.

This embodiment has the advantage of allowing much faster measurement.

According to a preferential embodiment, first and second linear InGaAs-type optical detectors 30, 32 are implemented. In fact, such detectors have sufficient sensitivity in the infrared in order to allow, for example, measurement rates of the order of 20,000 lines per second, which makes it possible to measure the surface of a 300 mm wafer in a few minutes.

Of course, other types of detectors; linear, array, CMOS, etc. can also be implemented in this embodiment.

A measurement method will now be described, which implements the device described in FIG. 3.

Firstly, as previously, the interferometer is balanced in order to produce the condition of equality of optical paths in a predefined measurement condition (for example the “normal” measurement situation 21a).

In order to carry out measurements, measurement lines are acquired simultaneously with the first optical sensor 30 and the second optical detector 32. The wafer is moved relative to the interferometer between acquisitions, in order to allow the acquisition of measurements on a surface. This movement can be continuous, at a constant speed.

Two interference images in opposite phase are thus obtained.

A contrast image is then calculated, for example by working out a ratio of the difference between the interference images and their sum.

On the basis of this contrast image, it is then possible to detect the defects as previously described in relation to FIG. 1 and FIG. 2.

With reference to FIG. 4, a third embodiment of a device according to the invention will now be described.

This embodiment makes it possible to obtain better contrast measurements than that in FIG. 3, while still maintaining a high measurement rate

In fact, utilizing only two images may lead in rare cases to poor contrast measurements, if the phase shift between the measurement 21 and reference 22 beams is exactly 180 degrees.

In this embodiment, the interferometer is produced in the form of a circulator:

it comprises a splitter element 41 in the form of a polarization splitter cube 41;

the light originating from the source 10 (wide spectrum, halogen type as previously) is polarized at 45 degrees to the axes of the splitter cube 41 by an input polarizer 40;

quarter-wave retardation plates 42 are inserted into the measurement and reference arms of the interferometer, with their axis placed at 45 degrees to the polarization of the incident light;

Thus, the measurement 21 and reference 20 beams emerge on a single side of the splitter cube 41 with cross-polarizations.

The interferometer is preferably in a Linnik configuration, with imaging optics 12 inserted into the measurement and reference arms, so as to minimize the divergence of the beams on passing through the polarizing elements.

The detection is carried out by an electro-optical modulator, 43, a polarizer 44 and an optical detector 45 in the form of a linear camera, preferably InGaAs.

The electro-optical modulator 43 is arranged so that its neutral axes are aligned with the respective polarizations of the measurement 21 and reference 20 beams that pass through it. Thus it is possible to introduce a phase shift between the measurement 21 and reference 20 beams, as a function of the applied voltage.

The polarizer 44 makes it possible to recombine the measurement 21 and reference 20 beams and so that they interfere at the level of the optical detector 45, It is oriented at 45 degrees with respect to the polarizations of the measurement 21 and reference 20 beams.

A measurement method will now be described, which implements the device described in FIG. 4.

Firstly, as previously, the interferometer is balanced in order to produce the condition of equality of optical paths in a predefined measurement condition (for example the “normal” measurement situation 21a).

In order to carry out measurements, for each point of the bonding zone 18, several interference images are acquired sequentially with the optical detector 45, by varying the phase shift between the measurement 21 and reference 20 beams with the electro-optical modulator 43. These acquisitions can be carried out at rates of several kilohertz, as they are only limited by the bandwidth of the electro-optical modulator (and the rate of the optical detector if applicable).

By choosing the phase shift introduced accordingly, it is possible to implement any known type of interferogram reconstruction technique by phase shifting (known as “phase stepping”) and thus deduce a contrast image therefrom.

It is possible for example to acquire 3 images that are phase-shifted by 120 degrees.

On the basis of this contrast image, it is then possible to detect defects as previously described in relation to FIG. 1 and FIG. 2.

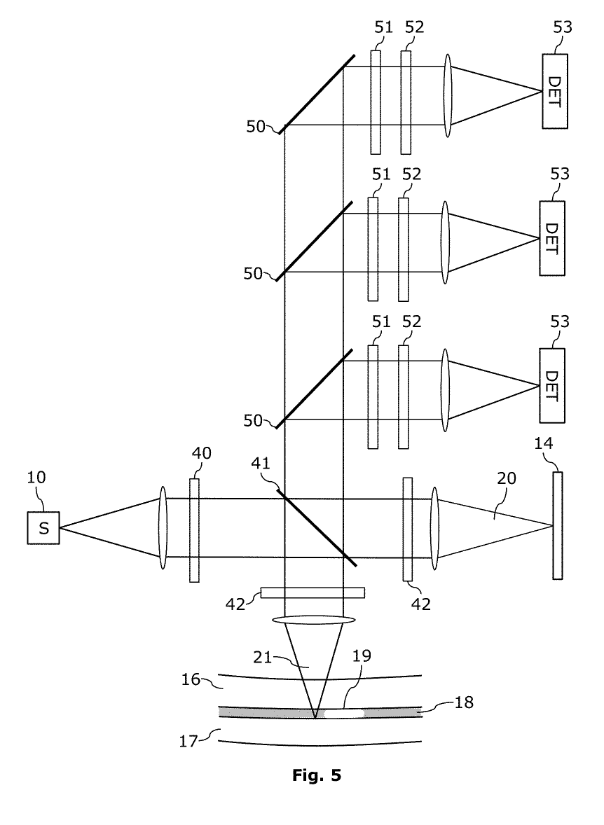

With reference to FIG. 5, a fourth embodiment of a device according to the invention will now be described.

In this embodiment, the interferometer is produced in the form of a circulator as described in relation to the embodiment in FIG. 4.

Thus, as previously, the measurement 21 and reference 20 beams emerge from a single side of the splitter cube 41 of the interferometer with cross-polarizations.

The detection is carried out by three assemblies constituted respectively by:

for at least two of them, a non-polarizing detection beam splitter 50 no for sampling a part of the measurement 21 and reference 20 beams;

for at least two of them, a retardation plate 51 the axes of which are aligned with the polarizations of the measurement 21 and reference 20 beams;

an optical detector 53 in the form of a linear camera preferably InGaAs;

a polarizer 52 placed in front of the optical detector 53, and after the retardation plate 51 if necessary. This polariser 52 is oriented at 45 degrees with respect to the polarizations of the measurement 21 and reference 20 beams, so as to recombine them and cause them to interfere on the optical detector 53.

Preferably, two retardation plates 51 of third wave type are implemented, one of which is oriented with its fast axis parallel to the polarization of the reference beam 20, and the other with its fast axis perpendicular to the polarization of the reference beam 20.

Thus, measurements of interferences I₁, I₂, I₃ are obtained simultaneously on the three optical detectors 53, phase shifted by −120 degrees, 0, +120 degrees, respectively.

After radiometric equalization of the three measurements, it is possible to calculate the contrast C at each point with the following relationship:

C=[(2I₁−(I₂+I₃)²)/3)²+(I₂−I₃)²]^{1/2}

A measurement method will now be described, which utilizes the device described in FIG. 5.

Firstly, as previously, the interferometer is balanced in order to produce the condition of equality of optical paths in a predefined measurement condition (for example the “normal” measurement situation 21a).

In order to carry out measurements, acquisitions are carried out simultaneously in-line with three optical detectors 53. In order to image a surface, the wafer is moved relative to the interferometer between the acquisitions. This movement can be continuous, at a constant speed.

Three interference images are thus obtained from which it is possible to calculate a contrast image C as previously described.

On the basis of this contrast image, it is then possible to detect the defects as previously described in relation to FIG. 1 and FIG. 2.

Of course, the invention is not limited to the examples which have just been described and numerous adjustments can be made to these examples without exceeding the scope of the invention.

1. A measurement device for inspecting a bonding zone between samples, comprising: a low coherence interferometer illuminated by a polychromatic light source with a measurement arm passing through said bonding zone and a reference arm;
at least one optical detector and optical and/or mechanical conditioning means arranged to allow the acquisition of at least two measurements of interferences with different phase conditions between a measurement optical beam originating from the measurement arm and a reference optical beam originating from the reference arm; and
calculation means arranged to calculate a contrast information of said interferences, and on the basis of said contrast information to search for defects in said bonding zone.

2. The device of claim 1, which comprises a low coherence interferometer operating by reflection.

3. The device of claim 1, which comprises mechanical conditioning means arranged so as to carry out at least one of the following functions:
varying the difference of optical path between the measurement arm and the reference arm of the interferometer;
moving the interferometer relative to the bonding zone so as to vary the optical path in the measurement arm; and
generating a movement along the axis of the reference optical beam of a reflective element so as to vary the optical path in the reference arm.

4. The device of claim 1, which comprises two optical detectors inserted in two output arms of the interferometer so as to allow two opposite phase measurements of interferences to be carried out.

5. The device of claim 1, which comprises an interferometer arranged so as to allow the generation of a measurement beam and a reference beam with substantially orthogonal polarizations.

6. The device of claim 5, which comprises an optical conditioning means in the form of a phase modulator inserted between the interferometer and an optical detector.

7. The device of claim 5, which comprises a plurality of optical detectors and optical conditioning means in the form of retardation plates arranged so as to allow the acquisition of a plurality of measurements of interferences with different phase conditions.

8. The device of claim 1, which comprises an optical detector or detectors with a plurality of measurement pixels, and optical imaging elements arranged so as to image the bonding zone according to at least one field of view on said optical detector or detectors.

9. A measurement method for inspecting a bonding zone between samples, comprising: utilizing a low coherence interferometer illuminated by a polychromatic light source and comprising a measurement arm with said bonding zone and a reference arm;
acquiring at least two measurements of interferences with different phase conditions between a measurement optical beam originating from the measurement arm and a reference optical beam originating from the reference arm;
calculating a contrast information of said interferences; and
searching, on the basis of said contrast information, for defects in said bonding zone.

10. The method of claim 9, which comprises a step of searching for defects in the form of voids or bubbles.

11. The method of claim 9, which comprises a step of adjusting the interferometer so that the optical path difference between the measurement arm and the reference arm is less than the coherence length of the light source when at least one of the following conditions is satisfied:
the measurement optical beam passes through a portion of the bonding zone without a defect;
the measurement optical beam passes through a part of the bonding zone with a defect of a predetermined nature.

12. The method of one of claim 9, which comprises a step of comparing an item of contrast information with a threshold or a range of contrast values.

13. The method of claim 9, which comprises steps:
of acquiring a plurality of contrast measurements; and
of detecting local variations in the contrast of said plurality of contrast measurements.

14. The method of claim 9, which comprises a step of sequential acquisition of a plurality of measurements of interferences by varying at the level of an optical detector the phase difference between the measurement beam and the reference beam.

15. The method of claim 9, which comprises a step of acquisition of a plurality of measurements of interferences of a plurality of optical detectors with different phase shifts between the measurement beams and the reference beams respectively incident on said optical detectors.

16. The method of claim 9, which is implemented for the search for defects in a bonding or adhesive zone between samples at least one of which is in the form of a wafer.
